(19) United States
(12) Patent Application Publication
(10) Pub. No.: US 2014/0261156 A1
(43) Pub. Date: Sep. 18, 2014

(54) Method of Forming a Crystallized Silicon Layer on the Surface of a Plurality of Substrates

(71) Applicant: COMMISSARIAT A L'ENERGIE ATOMIQUE ET AUX ENERGIES ALTERNATIVES, Paris (FR)

(72) Inventors: Virginie Brize, Saint Martin D'heres (FR); Jean-Paul Garandet, Le Bourget Du Lac (FR); Stephen Giraud, Chambery (FR); Etienne Pihan, La Motte Servolex (FR)

(21) Appl. No.: 14/349,987

(22) PCT Filed: Oct. 2, 2012
(86) PCT No.: PCT/IB2012/055272

§ 371 Date: Apr. 4, 2014

(30) Foreign Application Priority Data
Oct. 5, 2011 (FR) 11 58983

(51) Int. Cl. C30B 19/02; C30B 19/06

(52) U.S. Cl. CPC C30B 19/02; C30B 19/062
USPC 117/60; 117/64

(57) ABSTRACT

The present invention concerns a method of forming, by liquid phase epitaxial growth, on the surface of a plurality of substrates, a layer of crystallised silicon having a grain size greater than or equal to 200 μm, comprising at least the steps consisting of: (i) arranging a liquid bath formed from a liquid metal solvent phase in which liquid silicon is homogeneously dispersed; (ii) immersing, in the bath of step (i), said substrates (1), in such a way that each of the surfaces of the substrates (1) that need to be coated is in contact with the liquid bath, said surfaces being arranged parallel to one another, and perpendicularly to the interface (3) of the liquid bath (2) and the gas atmosphere (4) contiguous to said liquid bath or according to an inclination angle of at least 45° in relation to said interface (3); (iii) imposing, on the whole of step (ii), conditions conducive to the vaporisation of said liquid solvent phase and to the establishing of a natural convection movement of the liquid bath in the vicinity of the surfaces to be coated of the substrates, which are held in fixed position; and (iv) recovering the substrates coated with the crystallised silicon layer formed at the end of step (iii).

The present invention relates to a method of forming a thick layer of coarse-grained crystalline silicon on the surface of a plurality of substrates.

Such a layer is particularly advantageous with regard to its semiconducting properties in the context of the production of photovoltaic cells.

At present, photovoltaic cells are mainly manufactured starting from single-crystalline or polycrystalline silicon. The commonest chain of production for crystalline silicon employs the solidification of ingots from a bath of liquid silicon. These ingots are then cut into wafers, which can be transformed into photovoltaic cells.

Unfortunately, during the step of cutting these ingots into wafers, a considerable amount (up to 50%) of silicon is lost in sawing (“kerf loss”).

To avoid the loss of material that occurs during sawing of these ingots into wafers and thus reduce the costs of production of photovoltaic devices, techniques have been developed that aim to produce layers of crystalline silicon directly.

Thus, production of layers of silicon by the technology of liquid phase epitaxy has been proposed ([1], [2]).

This technique of liquid phase epitaxy consists more particularly of heating a liquid bath comprising this material and a solvent, for example tin or indium, to a high temperature, but below the melting point of the material to be deposited. In general, growth of the material to be crystallized is brought about by bringing the substrate to be coated in contact with the bath, then gradually lowering the bath temperature, generally at a rate from 0.1° C./min to 1° C./min. Since the solubility of the material to be deposited decreases with the temperature, the supersaturation induced by the cooling is translated into deposition of material on the substrate.

This technique advantageously gives thick layers of silicon of good crystalline quality, with a high solidification rate of the order of 5 to 50 μm/h and without loss of material.

Unfortunately, the conventional methods of liquid phase epitaxy require the use of single-crystalline silicon substrates. In fact, the use of so-called “low-cost” polycrystalline substrates is likely to cause problems of anisotropy of the rate of growth of the silicon and of attachment of solvent to the grain boundaries, making it impossible to obtain a homogeneous layer of crystalline silicon. However, these single-crystalline substrates with low levels of impurities have the drawback of being particularly expensive.

Moreover, the conventional technology of liquid phase epitaxy is generally carried out wafer by wafer. In fact, application of a system of collective deposition, which would permit the simultaneous treatment of several wafers in one and the same bath, is likely to pose problems in terms of control of deposition by the standard method of liquid phase epitaxy, in which, as mentioned above, supersaturation is induced by gradual cooling of the bath. In fact, for a bath comprising a plurality of substrates, it proves difficult to ensure uniformity of temperature (and therefore of the rate of deposition) for cooling rates compatible with the production of layers with good crystalline quality.

As an illustration of these standard techniques of liquid phase epitaxy, reference may notably be made to document US 2003/140859, which describes precisely a method of forming thin films of semiconductor material on the surface of a plurality of substrates. This method involves immersing the substrates in a liquid bath of silicon, growth of the layers of silicon being assured by gradual cooling of this liquid bath. It should be noted that in this document the surfaces of the substrates are arranged so as to prevent any phenomenon of convection, as the latter is considered there to be detrimental to the homogeneity of the deposit to be formed.

Consequently, the standard techniques of liquid phase epitaxy are unable to give complete satisfaction in terms of reduction of the costs of production of the layers of crystalline silicon for applications in photovoltaics.

The aim of the present invention is precisely to propose a method for obtaining homogeneous layers of silicon of good quality easily and economically.

In particular, the present invention proposes a method of forming layers of crystalline silicon, which can overcome the aforementioned drawbacks of the conventional technologies of liquid phase epitaxy.

More precisely, according to a first of its aspects, the present invention relates to a method of forming, by liquid phase epitaxial growth, and on the surface of a plurality of substrates, a layer of crystalline silicon having a grain size greater than or equal to 200 μm, comprising at least the steps consisting of:

(i) providing a liquid bath formed from a liquid metallic solvent phase, in which liquid silicon is dispersed uniformly;

(ii) immersing said substrates in said bath from step (i), the surfaces of said substrates that are to be coated being arranged parallel to one another and the gap between two consecutive substrates being compatible with a convective motion of said liquid bath between these substrates, and

(iii) maintaining the whole at a temperature favorable to the vaporization of said liquid solvent phase to form said layer of crystalline silicon at the interface between each of said faces to be coated and said liquid bath,

characterized in that the surfaces of said substrates are arranged, in the liquid bath, perpendicularly to the interface that exists between the liquid bath and the gas atmosphere contiguous with said liquid bath or at an angle of inclination of at least 45° relative to said interface.

The angle of inclination is defined such that at 90°, the surfaces of the substrates are perpendicular to said interface.

In particular, the substrates are held in a fixed position during step (iii) of forming said layer of crystalline silicon.

The present invention relates more particularly to a method of forming a layer of crystalline silicon having a grain size greater than or equal to 200 μm on the surface of a plurality of substrates, by liquid phase epitaxial growth, comprising at least the steps consisting of:

(i) providing a liquid bath (2) formed from a liquid metallic solvent phase, in which liquid silicon is dispersed uniformly;

(ii) immersing said substrates (1) in the bath from step (i), so that each of the surfaces of the substrates (1) that are to be coated is in contact with the liquid bath, said surfaces being arranged parallel to one another, and perpendicularly to the interface (3) of the liquid bath (2) and gas atmosphere (4) contiguous with said liquid bath or at an angle of inclination of at least 45° relative to said interface (3);

(iii) imposing, on the whole of step (ii), conditions favorable to the vaporization of said liquid solvent phase and to the establishment of a natural convective motion of the liquid bath (2) in the vicinity of the surfaces to be coated of the substrates (1) held in a fixed position; and

(iv) recovering the substrates coated with the layer of crystalline silicon formed at the end of step (iii).

“Fixed position” means that the substrates are not imparted any mechanical motion, throughout the period of formation of said layer of crystalline silicon.

“Natural” convection means that the convective motion results from a gradient, in particular from a concentration gradient, as explained in more detail later. This natural convection is to be distinguished from so-called forced convection, caused by an external motive force applied to a fluid (magnetic fields, imposed rotation of the substrate and/or of the crucible, vibrations of the bath, etc.).

According to a particular embodiment, the substrates are spaced apart in the liquid bath, the distance between two consecutive substrates being compatible with a convective motion of said liquid bath between these substrates for homogenizing the bath.

The liquid bath considered in step (iii) can be maintained at a temperature at least equal to 1000° C. Vaporization of the liquid solvent phase takes place more particularly in step (iii) according to an evaporative flux developing parallel to the surfaces of the substrates to be treated.

According to a particular embodiment, steps (i), (ii) and (iii) are successive. In particular, the method of the invention does not require cooling of the liquid bath, during or between any one of steps (i), (ii) and (iii).

Moreover, in contrast to conventional techniques of liquid phase epitaxy, the method of the invention does not require gradual cooling of the bath for formation of the layers of silicon.

According to another particular embodiment, the method according to the invention for forming layers of crystalline silicon on the surface of a plurality of substrates can consist of the aforementioned four successive steps (i), (ii), (iii) and (iv).

The method of the invention proves advantageous in several respects.

First, it can provide collective treatment of a plurality of substrates, i.e. simultaneous deposition of a layer of crystalline silicon on the surface of a plurality of substrates. Such collective treatment offers an obvious advantage in terms of productivity and cost on an industrial scale.

Moreover, advantageously, the method of the invention can employ inexpensive base substrates, of the metallurgical silicon type. “Substrate of the metallurgical type” denotes substrates of polycrystalline silicon, containing impurities, notably metallic, such as Fe, Cr, Cu . . . , at far higher concentrations than a single-crystalline silicon substrate of electronic grade. These so-called “low-cost” silicon substrates can also be obtained from ingots produced by directional solidification, which can reduce the amount of impurities to contents of the order of a few ppm.

The use of substrates of the metallurgical silicon type as substrates for photovoltaic applications, even if purified beforehand by directional solidification, was not in any way obvious, in view of the temperatures employed according to the method of the invention (preferably of at least 1000° C.), being higher than the temperatures usually employed in conventional methods of liquid phase epitaxy, which generally do not exceed 900° C.

In fact, these substrates of the low cost type contain appreciable amounts of metallic elements (of the order of some ppb to some ppm), which are likely to diffuse in the active layer, the more so the higher the temperature of growth employed. Above 1250° C., even dopants such as boron and phosphorus have significant mobility and can diffuse over several micrometers in the space of a few hours.

Against all expectation, the inventors found that it is possible to obtain layers of good quality, even for high temperatures of vaporization of the metallic solvent phase in step (iii) of the method of the invention, in particular above 1000° C., notably above 1050° C.

Moreover, the method of the invention is particularly easy to apply, and step (iii) of liquid phase epitaxy can be carried out at constant temperature. Thus, the method according to the invention proves particularly advantageous compared to the conventional techniques of liquid phase epitaxy, in which control of the cooling of the liquid bath at a constant rate is particularly difficult and demanding.

Finally, the method of the invention makes it possible to obtain continuous, homogeneous layers of coarse-grained crystalline silicon, in particular having a grain size greater than or equal to 200 μm, notably greater than or equal to 300 μm, in particular greater than or equal to 500 μm, preferably greater than or equal to 1 mm, and more preferably greater than or equal to 2 mm. Such a crystallographic structure advantageously ensures high efficiencies of energy conversion when used in a photovoltaic cell.

Such a method is all the more surprising as it is known from the prior art [3] that evaporation of the solvent at the interface between the bath and the contiguous gas atmosphere leads to a change in bath composition according to a vertical concentration gradient. Consequently, it might be expected that vaporization of the solvent along a parallel line to the substrates would lead to the deposition of layers of silicon of nonuniform thickness on the surface of the substrates.

However, against all expectation, the inventors discovered that it is possible to obtain continuous, homogeneous layers of crystalline silicon of good quality, notably of large grain size, employing the specific conditions of deposition mentioned above.

Without wishing to be bound to a theory, the conditions of carrying out the method according to the invention, in particular the specific configuration of the substrates and control of the temperature for vaporization of the liquid solvent phase, make it possible to generate a natural convective motion in the vicinity of the surfaces of the substrates that are to be coated, sufficiently intense to overcome the concentration gradient induced by evaporation of the solvent.

More precisely, without wishing to be bound to a theory, the method of the invention probably involves several mechanisms, shown schematically in FIG. 1 and described below.

In particular, evaporation of the metallic solvent (2) leads to precipitation of silicon by epitaxy on said surfaces of the substrates (1), to compensate the loss of thermodynamic equilibrium induced by evaporation. For a given total area of the substrates, an evaporative flux (amount of matter evaporated in unit time) is therefore translated into a solidification rate.

As the silicon is deposited on the substrate (1), there is rejection of solvent at the growth front of the layer of silicon. In the vicinity of the front, the concentration of solvent is therefore higher (C_{S1}>C_{S2}), and decreases in the direction perpendicular to the substrate (formation of a solute boundary layer). Since the silicon and the metallic solvent do not have the same density, this concentration gradient imposes a density gradient (∇ρ) perpendicular to the substrate.

This density gradient (∇ρ) constitutes the motive force for natural convection by the formation of a vortex resulting from the vector product (∇ρ×g) of the density gradient (∇ρ) perpendicular to the substrate and gravity (g). More precisely, the curl of the Navier-Stokes equation shows that the motive force for convection is proportional to the vector product of the density gradient and gravity. For example, using H to denote the characteristic dimension of the vortex generated between two substrates to be coated, a scale law analysis of the vorticity equation written in a laminar steady state shows that the order of magnitude of the convection velocity V is given by:

V˜|∇ρ×g|H³/η

where ρ and η denote respectively the density and the dynamic viscosity of the liquid, g is the acceleration of gravity, and the symbol ∇ represents the derivative operator nabla. A scale of length for H is for example half the distance between two consecutive substrates.

This natural convective motion can thus be sufficiently intense to homogenize the solute concentration in the vertical direction. In particular, it is possible to attain a sufficient level of convection by providing a reasonable gap between the substrates, owing to the power 3 attached to H in the aforementioned equation.

The density difference between silicon (ρ_{Si}=2.53 g.cm⁻³) and the metallic solvent or solvents employed according to the invention, such as indium or tin (ρ_{In}=7.31 g.cm⁻³ and μ_{Sn}=7.29 g.cm⁻³), also guarantees establishment of an efficient convective motion.

Regarding the convective motion, it should be noted that the maximum convection velocity in the bath can be greater than or equal to 5 mm/s. Such a velocity can ensure sufficient mixing of the bath.

The invention will be better understood on reading the detailed description given below and the examples of carrying out the invention, and on examining the appended drawings, in which:

FIG. 1 shows schematically the physical phenomena generated by the specific conditions of carrying out the method of the invention in the vicinity of a substrate;

FIG. 2 shows schematically variants of arrangement of the substrates in the liquid bath, inclined at an angle of orientation a greater than 45° relative to the interface of the liquid bath and the gas atmosphere (FIG. 2a) or perpendicular to this interface (FIG. 2b);

FIG. 3 shows schematically the configuration according to the invention of two substrates in a liquid bath, allowing convective motion of the liquid bath between these substrates;

FIG. 4 shows a boat of the graphite basket type for holding the substrates in the desired configuration;

FIG. 5 shows schematically an installation for producing crystalline silicon for implementing the method of the invention.

Hereinafter, the expressions “between . . . and . . . ”, “ranging from . . . to . . . ” and “varying from . . . to . . . ” are equivalent and signify that the limits of the range are included, unless stated otherwise.

Unless stated otherwise, the expression “having/comprising a/one” must be understood as “having/comprising at least one”.

Substrates

As stated above, the method of the invention advantageously proposes a system for collective deposition, permitting parallel treatment of a plurality of substrates in one and the same bath.

“A plurality of substrates” thus means at least two substrates.

Of course, the number of substrates treated simultaneously according to the method of the invention depends on the volume of the liquid bath used, or else on the size, in particular the thickness, of the substrates to be treated.

For example, the method of the invention can employ from 5 to 50 substrates.

In the context of the present invention, the term “substrate” refers to a solid base structure, with the layer of crystalline silicon formed on at least one of its faces.

The substrates employed in the method of the invention can more particularly be in the form of wafers. Said substrates are arranged relative to one another in such a way that the surfaces that are to be treated are arranged parallel to one another. Layers of crystalline silicon can thus be formed according to the method of the invention simultaneously on the two parallel surfaces of such substrates.

The substrates employed in the method of the invention can be identical or different. Preferably, they are identical. Employment of identical substrates advantageously allows optimization of their disposition within the liquid bath, and therefore of the number of substrates introduced in one and the same liquid bath.

The substrates employed can be single-crystalline or polycrystalline silicon substrates. They can comprise grains having a size from 1 mm to 1 cm, preferably from 5 mm to 1 cm.

Of course, the method of the invention is not limited to employing substrates of a particular type. However, for obvious reasons, it is preferable to use substrates of metallurgical silicon, also called “low-cost” substrates, which are inexpensive relative to single-crystalline silicon substrates of electronic grade.

These silicon substrates may notably comprise higher concentrations of impurities than the electronic-grade silicon known by a person skilled in the art.

The silicon substrates can thus comprise metallic impurities such as Fe, Ti, Cr, Cu, at a content less than or equal to 20 ppm, more particularly ranging from 1 to 10 ppm. These metallic impurities can more particularly be iron or aluminum.

The content of metallic impurities can for example be determined by the technique of Glow Discharge Mass Spectroscopy.

The silicon substrates employed in the method of the invention can also comprise one or more dopants, in particular one or more P type dopants and/or of the N type, and more particularly at least one dopant of the P type, notably boron, and at least one dopant of the N type, notably phosphorus.

These dopants can be present at a content ranging from 5 to 50 ppm by weight.

According to a particular embodiment, the silicon substrates are obtained from ingots produced by directional solidification, then cut into wafers, according to techniques well known by a person skilled in the art.

Directional solidification is generally carried out firstly by melting the raw material partially or completely, then submitting it to a cooling phase after thermal stabilization. The method of directional solidification creates a surface layer containing the impurities at the end of the ingot, which will then be removed (scalping step).

Directional solidification can reduce the contents of metallic impurities present in silicon substrates.

The silicon substrates obtained by directional solidification can thus have a total content of metallic impurities of the order of a few ppm, in particular ranging from 1 to 5 ppm.

The silicon substrates employed in the method of the invention can have a thickness ranging from 100 to 600 μm, in particular from 150 to 500 μm, preferably from 250 to 400 μm.

Prior to their treatment according to the method of the invention, the silicon substrates can optionally be submitted to a surface texturing step, in particular of the surface or surfaces on which the layer of crystalline silicon will be formed.

“Surface texturing” means creating a succession of hollows and reliefs on said surface. This texturing step makes it possible for example to create patterns of the order of 10 μm.

This surface treatment can advantageously reduce reflectivity.

The texturing of the surface of a silicon substrate can be carried out for example by acidic or basic chemical treatments, according to methods known by a person skilled in the art, notably by treatment with an alkaline solution, for example of potassium hydroxide, or an acid solution.

According to a particular embodiment, before being immersed in the liquid bath in step (ii) of the method of the invention, the substrates can be treated with hydrofluoric acid or immersed in a bath of aluminum, for surface deoxidation of the substrates.

Step (i): Liquid Bath

As stated above, the liquid bath employed in the method of the invention is formed from a liquid metallic solvent phase, in which liquid silicon is dispersed uniformly.

The metallic solvent is more particularly selected from solvents having sufficient volatility to allow their evaporation in step (iii) of the method of the invention.

It can be selected more particularly from indium, tin, copper, gallium and alloys thereof. According to an especially preferred embodiment, said liquid metallic solvent is selected from indium, tin and alloys thereof.

Of course, a person skilled in the art will adapt the volume of the liquid bath to be used in the method of the invention, notably with regard to the number of substrates to be treated, their size and thickness.

Of course, the amount of liquid silicon introduced in the liquid bath is likely to vary, notably as a function of the number of surfaces to be treated, the process temperature and the desired thickness of the layers of crystalline silicon.

The preparation of such a liquid bath, classically employed in the conventional techniques of liquid phase epitaxy, forms part of the general knowledge of a person skilled in the art.

According to a first embodiment variant, said liquid bath in step (i) can be formed beforehand by adding solid silicon to a liquid solvent phase heated to a temperature between 800 and 1350° C.

According to another embodiment variant, said liquid bath can be formed by solid-phase mixing of the silicon and the metallic solvent intended to form said liquid solvent phase, then heating the mixture to a temperature between 800 and 1350° C.

A person skilled in the art will employ appropriate heating temperatures to obtain a completely liquid bath comprising said liquid metallic solvent and said liquid silicon.

Thus, a liquid bath of tin and silicon can be prepared by heating a solid-phase mixture of tin and silicon to a temperature of about 1150° C.

According to another embodiment variant, a liquid bath of indium and silicon can be prepared by heating a solid-phase mixture of indium and silicon to a temperature of about 1000° C.

As discussed in greater detail later, said liquid bath can be prepared in a graphite crucible (optionally coated with a layer of SiC) that withstands heating at high temperatures suitable for obtaining said liquid bath.

According to a particular embodiment, said liquid bath can moreover incorporate at least one dopant selected from the P type dopants, for example aluminum (Al), gallium (Ga), indium (In), boron (B), and the N type dopants, for example antimony (Sb), arsenic (As), phosphorus (P), and mixtures thereof.

These dopants can be present in a proportion ranging from 0.05 to 5 atomic ppm, preferably 0.1 to 1 atomic ppm.

Step (ii): Immersion of the Substrates in the Liquid Bath

In a second step of the method of the invention, the substrates to be treated are immersed in the liquid bath as described above.

According to an essential feature of the method of the invention, said substrates are arranged in said liquid bath according to a configuration such that:
the surfaces of said substrates that are to be coated are in contact with the liquid bath;
the surfaces of said substrates that are to be coated are arranged parallel to one another; and
the surfaces of said substrates are arranged in the liquid bath perpendicularly to the interface of the liquid bath and the gas atmosphere above the liquid bath, or at an angle of inclination of at least 45° relative to said interface.

FIG. 2 shows schematically two variants according to the invention of arrangements of two substrates (1) in a liquid bath (2).

According to a particular embodiment, as shown in FIG. 2a, the substrates (1) can be inclined in the liquid bath (2). The angle of inclination a of the surfaces of said substrates (1) relative to the interface (3) of the liquid bath (2) and the gas atmosphere (4) is greater than or equal to 45°.

According to an especially preferred embodiment, as shown in FIG. 2b, the surfaces of said substrates (1) are arranged in said liquid bath (2) perpendicularly to the interface (3) of the liquid bath (2) and the gas atmosphere (4).

The substrates are more particularly positioned in the liquid bath so as to allow, during step (iii), a natural convective motion in the vicinity of each of the surfaces of the substrates that are to be coated.

According to a particular embodiment, as shown in FIGS. 2 and 3, the substrates are spaced apart, the gap (h) between two consecutive substrates being adjusted so as to ensure that there is convective motion of said liquid bath between the substrates.

A person skilled in the art will be able to adjust the gap (h) between the substrates to allow natural convective motion of the liquid bath, sufficient for homogenization of the bath.

According to a particular embodiment, the gap between two consecutive substrates is such that it provides a gap (h) from 5 to 25 mm, preferably from 10 to 20 mm between their respective external surfaces, as shown in FIG. 3.

Of course, the method of the invention is not limited to the variants specifically described and shown in FIGS. 2 and 3. Other variants can be envisaged provided the conditions specified above, relating to the configuration of the different surfaces to be treated, are respected.

According to a particular embodiment, notably in the case when we wish to form a layer of crystalline silicon on the surface of only one of the faces of the substrates, said substrates can be arranged back to back, in other words with their faces that are not to be treated placed together.

Such an arrangement advantageously makes it possible to increase the number of samples that can be treated simultaneously in the liquid bath, and thus increase the productivity of the method of the invention.

As discussed in greater detail in the description of the installation for producing crystalline silicon given below, the substrates can be arranged in a boat (5) such as is shown in FIG. 4, so that the surfaces of said substrates to be crystallized can be held in said liquid bath at an angle of inclination (α) of at least 45° relative to the horizontal, preferably in the vertical position, and a gap (h) can be provided between two consecutive substrates favorable to convective motion of said bath in said gap.

Step (iii): Formation of the Layer of Crystalline Silicon

According to a third step of the method of the invention, the whole of step (ii) is exposed to conditions, in particular temperature conditions, favorable to the vaporization of said liquid solvent phase and to the establishment of a natural convective motion of the liquid bath in the vicinity of the surfaces of the substrates that are to be coated, to form a layer of crystalline silicon at the interface between each of the faces to be coated and said liquid bath.

In particular, the liquid bath in which the substrates are immersed is maintained at a temperature favorable to the vaporization of said liquid solvent phase.

Advantageously, step (iii) can be carried out while maintaining a constant temperature permitting vaporization of the liquid solvent phase. As mentioned above, the method according to the invention thus proves particularly advantageous, compared to the conventional techniques of liquid phase epitaxy, in which the liquid bath must be cooled uniformly.

In particular, said liquid bath considered in step (iii) is maintained at a temperature ranging from 800° C. to 1350° C., more particularly at a temperature at least equal to 1000° C.

According to a particular embodiment, said liquid bath considered in step (iii) is maintained at a temperature equal at most to 1200° C.

Of course, the temperature to be employed for vaporization of the liquid solvent phase in step (iii) may vary depending on the nature of the liquid metallic solvent used.

Thus, according to a particular embodiment, deposition can be carried out in a liquid bath of tin and silicon, the temperature of which is maintained between 1100° C. and 1200° C. in step (iii).

According to another particular embodiment, deposition can be carried out in a liquid bath of indium and silicon, the temperature of which is maintained between 1000° C. and 1100° C. in step (iii).

Step (iii) of the method of the invention can be carried out for a time in the range from 1 hour to 4 hours, preferably from 2 hours to 3 hours.

Of course, the liquid bath can be maintained at the appropriate temperature by any heating technique known by a person skilled in the art and classically employed in conventional techniques of liquid phase epitaxy.

According to a particular embodiment, step (iii) is carried out by heating the graphite crucible (optionally with silicide treatment) containing said liquid bath in which the substrates are immersed, using suitable heating devices.

A person skilled in the art will be able to adjust the duration of vaporization of said liquid solvent phase in step (iii) depending on the area of the surfaces on which the layer of crystalline silicon is to be formed, and the desired thickness of said layer.

According to an especially preferred embodiment, steps (i), (ii) and (iii) of the method of the invention are carried out successively.

More particularly, steps (i), (ii) and (iii) can be carried out successively by maintaining, in steps (ii) and (iii), the temperature of the liquid bath considered in step (i). In other words, carrying out the method of the invention does not require lowering the temperature during or between any one of steps (i), (ii) and (iii).

According to said embodiment variant, said liquid bath can thus be formed by heating a solid mixture of metallic solvent and silicon to a high temperature suitable for obtaining a liquid bath, notably ranging from 850 to 1350° C. The substrates are then immersed in this liquid bath immediately. Then, the whole is maintained at this temperature for a suitable time for vaporization of the liquid solvent phase.

As stated above, the layers of crystalline silicon, formed simultaneously at the end of step (iii) on the surface of each of the silicon substrates, are continuous and homogeneous, and are of good quality, suitable in particular for use thereof in a photovoltaic device.

More particularly, the layers of crystalline silicon obtained have a grain size greater than or equal to 200 μm.

In particular, the grain size of said layers can be greater than or equal to 300 μm, in particular greater than or equal to 500 μm, preferably greater than or equal to 1 mm and more preferably greater than or equal to 2 mm.

The average size of the grains of crystalline silicon can be measured by light microscopy or with the scanning electron microscope.

Moreover, the layers of crystalline silicon on the surface of each of the substrates employed in the method of the invention have good uniformity in terms of thickness. More particularly, the variation in thickness of the layer of silicon on one and the same surface does not exceed 15%, preferably 10%, in particular 5% and more preferably 2%.

The layers of silicon formed can more particularly have a thickness in the range from 5 to 50 μm, notably from 10 to 20 μm.

Installation for Producing Crystalline Silicon

According to another of its aspects, the present invention relates to an installation for producing crystalline silicon, notably suitable for carrying out the method described above, comprising:
a crucible,
at least two substrates, oriented at an angle of inclination of at least 45° to the horizontal, and defining at least two crystallization surfaces arranged parallel to one another, the substrates being positioned within the crucible so as to be immersed in a bath of liquid solvent formed from liquid silicon dispersed homogeneously in a liquid metallic solvent phase, and if necessary,
a chamber for confining the vapors of the liquid solvent phase, above the bath.

Characteristic features of the installation for producing crystalline silicon according to the invention will become clear on reading the following description, given purely as a nonlimiting example and referring to the appended FIGS. 4 and 5.

As mentioned above, such an installation can comprise a boat (5), for keeping the substrates at an angle of inclination of at least 45° to the horizontal, preferably vertically. In FIG. 4, the boat comprises closed walls, but an open boat (without walls) can also be envisaged, so as to favor the introduction of the liquid into said boat.

The boat (5) can have grooves, preferably vertical, in which the substrates in the form of wafers are fitted, with a gap, preferably regular, between two consecutive substrates that is favorable to convective motion of said bath in said gap.

The boat (5) can be supported by a vertically movable rod (6). Such a rod advantageously allows the substrates held in the boat to be lowered into the crucible (7) containing said liquid bath (2) for step (ii) of the method of the invention. The bottom portion of the rod carrying the boat can be of graphite, so as to be able to withstand the high temperatures of the liquid bath during introduction of the boat into the liquid bath. The top portion can also be of graphite or of some other material such as alumina.

The installation can comprise a motorized system, not shown in FIG. 5, for lowering, raising and rotating the boat automatically.

The crucible (7) comprising the bath of liquid solvent can more particularly be a graphite crucible, in particular silicide-treated.

The installation can further comprise a heating means (10) known by a person skilled in the art, making it possible, by heating the crucible, to heat the liquid bath that it contains to the desired temperature, as described above.

The chamber (8) for confining the vapors of said liquid solvent phase can include a screen (9) placed above the crucible for recovering the liquid solvent phase, during vaporization thereof in step (iii) according to the method of the invention.

This screen (9) advantageously allows recycling of the liquid solvent phase by condensation of the latter on the cooled screen.

Of course, other elements can be included in the installation according to the invention.

The conceivable variants for the installation for production of silicon according to the invention, for implementing steps (i), (ii), (iii) and (iv) of the method of the invention, also form part of the invention.

The examples given hereunder are nonlimiting and are purely for illustrating invention.

### EXAMPLE 1

The method of the invention is carried out using an installation such as is shown in FIG. 5.

Twenty substrates in the form of wafers (dimensions 10×10 cm) of metallurgical silicon purified by directional solidification are arranged in a boat (5) for keeping them in the vertical position, with a gap between two consecutive substrates of 1 cm.

First, boat (5) is positioned in the top portion of the installation.

Step (i): Preparation of the Liquid Bath

A charge of tin and silicon (98.48% tin+1.52% silicon by weight) is put in a graphite crucible (7). The mixture is heated to a high temperature (1150° C.) in order to obtain a homogeneous liquid bath (bath volume of 9500 cm³) formed from liquid silicon dispersed in liquid tin.

Step (ii): Immersion of the Substrates

When the system has reached a temperature of 1150° C., the boat containing the substrates is introduced into the liquid bath to allow growth of the layers of crystalline silicon on the surface of the substrates.

Step (iii): Vaporization of the Solvent

The temperature of the liquid bath is maintained at 1150° C. The solvent evaporates with evaporative flux parallel to the substrates. Vaporization is maintained for about 2 hours.

The boat is then removed from the liquid bath.

The layers of crystalline silicon formed on the surface of the substrates are continuous and homogeneous. They have a constant thickness on all of the surfaces to be crystallized of about 16 μm. The average size of the grains of crystalline silicon, measured with the light microscope, is about 400 μm.

### EXAMPLE 2

The method of the invention is carried out using an installation such as is shown in FIG. 5.

Twenty substrates in the form of wafers (dimensions 10×10 cm) of purified metallurgical silicon are arranged in a boat (5) for holding them in the vertical position, with a gap between two consecutive substrates of 1 cm.

First, the boat (5) is positioned in the top portion of the installation.

Step (i): Preparation of the Liquid Bath

A charge of indium and silicon (0.97 moles of indium+0.03 moles of silicon) is put in a graphite crucible (7). The mixture is heated to a high temperature (1000° C.) in order to obtain a homogeneous liquid bath (bath volume of 9500 cm³) formed from liquid silicon dispersed in liquid indium.

Step (ii): Immersion of the Substrates

When the system has reached a temperature of 1000° C., the boat containing the substrates is introduced into the liquid bath to allow growth of the layers of crystalline silicon on the surface of the substrates.

Step (iii): Vaporization of the Solvent

The temperature of the liquid bath is maintained at 1000° C. The solvent evaporates with evaporative flux parallel to the substrates. Vaporization is maintained for about 4 hours.

The boat is then removed from the liquid bath.

The layers of crystalline silicon formed on the surface of the substrates are continuous and homogeneous. They have a constant thickness on all of the surfaces to be crystallized of about 20 μm. The average size of the grains of crystalline silicon, measured with the light microscope, is about 300 μm.

### REFERENCES

[1] Peter et al., “Thin film silicon solar cells on upgraded metallurgical silicon substrates prepared by LPE”, Solar Energy Materials and Solar Cells 74 (2002) 219

[2] Olchowik et al., “Influence of LPE process technological conditions on Si ELO layers morphology”, J. Non Crystalline Solids 354 (2008) 4287

[3] Pelliciari et al., “A new growth method for CdTe: a breakthrough toward large areas”, J. Electronic Materials, 34 (2005) 693-698.

1.-14. (canceled)

15. A method of forming a layer of crystalline silicon having a grain size greater than or equal to 200 μm, by liquid phase epitaxial growth on the surface of a plurality of substrates, comprising the steps of:
(i) providing a liquid bath formed from a liquid metallic solvent phase, in which liquid silicon is dispersed uniformly;
(ii) immersing said substrates in the bath from step (i), so that each of the surfaces of the substrates that are to be coated is in contact with the liquid bath, said surfaces being arranged parallel to one another, and perpendicularly to the interface of the liquid bath and gas atmosphere contiguous with said liquid bath or at an angle of inclination of at least 45° relative to said interface;
(iii) imposing, on the whole of step (ii), conditions favorable to the vaporization of said liquid solvent phase and to establishment of a natural convective motion of the liquid bath in the vicinity of the surfaces to be coated of the substrates held in a fixed position; and
(iv) recovering the substrates coated with the layer of crystalline silicon formed at the end of step (iii).

16. The method of claim 15, wherein said liquid bath considered in step (iii) is maintained at a temperature at least equal to 1000° C.

17. The method of claim 15, wherein said liquid bath considered in step (iii) is maintained at a temperature equal at most to 1200° C.

18. The method of claim 15, wherein step (iii) is carried out for a time ranging from 1 to 4 hours.

19. The method of claim 15, wherein the substrates are spaced apart to form at least one gap between two consecutive substrates that is compatible with a natural convective motion of said liquid bath between these substrates.

20. The method of claim 15, wherein the substrates are spaced apart to provide a gap from 5 to 25 mm between their respective external surfaces for homogenizing the bath.

21. The method of claim 15, wherein the surfaces of said substrates are arranged in step (ii) in said liquid bath, perpendicularly to the interface of the liquid bath and the gas atmosphere.

22. The method of claim 15, wherein said substrates are arranged in a boat configured for holding the surfaces of said substrates to be crystallized in said liquid bath at an angle of inclination (α) of at least 45° relative to the horizontal, and for providing a gap between two consecutive substrates favorable to convective motion of said bath in said gap.

23. The method of claim 15, wherein said liquid metallic solvent is selected from indium, tin, copper, gallium, and alloys thereof.

24. The method of claim 15, wherein said liquid bath additionally incorporates at least one dopant selected from aluminum, gallium, indium, boron, antimony, arsenic, phosphorus and mixtures thereof.

25. The method of claim 15, wherein deposition is carried out in a liquid bath of tin and silicon the temperature of which is maintained between 1100° C. and 1200° C. in step (iii).

26. The method of claim 15, wherein deposition is carried out in a liquid bath of indium and silicon the temperature of which is maintained between 1000° C. and 1100° C. in step (iii).

27. The method of claim 15, wherein said liquid bath in step (i) is formed beforehand by:
adding solid silicon to a liquid metallic solvent phase heated to a temperature between 800 and 1350° C.; or
solid phase mixing of silicon and at least one metallic solvent intended to form said liquid solvent phase, and heating the mixture to a temperature between 800 and 1350° C.

28. The method of claim 15, wherein the layer of crystalline silicon obtained at the end of step (iii) has a grain size greater than or equal to 300 μm.

29. The method of claim 15, wherein the layer of crystalline silicon obtained at the end of step (iii) has a thickness in the range from 5 to 50 μm.
